(19) United States
(12) Patent Application Publication
(10) Pub. No.: US 2007/0003842 A1
(43) Pub. Date: Jan. 4, 2007

(54) Software sequencer to dynamically adjust wafer transfer decision

(75) Inventors: Chongyang Wang, San Jose, CA (US); Serguei 'Serge' Platonov, Palo Alto, CA (US)

Correspondence Address: TOWNSEND AND TOWNSEND AND CREW LLP / AMAT, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 11/436,139

(22) Filed: May 17, 2006

Related U.S. Application Data
(60) Provisional application No. 60/695,262, filed on Jun. 29, 2005.

(51) Int. Cl. G03F 1/00; H01L 21/66

(52) U.S. Cl. 430/5; 438/14

(57) ABSTRACT

A method of operating a track lithography tool. The track lithography tool is adapted to process a plurality of substrates according to a recipe, the recipe including a plurality of process steps and a plurality of transfer steps. The method includes determining a process time associated with a time critical process and determining an initial sending rate for the track lithography tool. The method also includes transferring at least one of a plurality of wafers into the track lithography tool at the initial sending rate and monitoring a variation in the process time associated with the time critical process. The method further includes increasing the duration of at least one of the plurality of process steps, wherein the duration of the at least one of the plurality of process steps is increased by an amount equal to the variation in the process time associated with the time critical process.

### CROSS-REFERENCES TO RELATED APPLICATIONS

This application claims priority to U.S. Provisional Application No. 60/695,262, filed Jun. 29, 2005, the disclosure of which is hereby incorporated by reference in its entirety for all purposes.

### BACKGROUND OF THE INVENTION

The present invention relates generally to the field of substrate processing equipment. More particularly, the present invention relates to a method and apparatus for transferring substrates during processing in a track lithography tool. Merely by way of example, the invention has been applied to dynamically adjust a wafer transfer decision in real-time as wafers move through a multi-chamber track lithography tool. The method and apparatus can be applied to other processes for semiconductor substrates, for example those used in the formation of integrated circuits.

Modern integrated circuits contain millions of individual elements that are formed by patterning the materials, such as silicon, metal and/or dielectric layers, that make up the integrated circuit to sizes that are small fractions of a micrometer. The technique used throughout the industry for forming such patterns is photolithography. A typical photolithography process sequence generally includes depositing one or more uniform photoresist (resist) layers on the surface of a substrate, drying and curing the deposited layers, patterning the substrate by exposing the photoresist layer to electromagnetic radiation that is suitable for modifying the exposed layer and then developing the patterned photoresist layer.

It is common in the semiconductor industry for many of the steps associated with the photolithography process to be performed in a multi-chamber processing system (e.g., a cluster tool) that has the capability to sequentially process semiconductor wafers in a controlled manner. One example of a cluster tool that is used to deposit (i.e., coat) and develop a photoresist material is commonly referred to as a track lithography tool.

Track lithography tools typically include a mainframe that houses multiple chambers (which are sometimes referred to herein as stations or modules) dedicated to performing the various tasks associated with pre- and post-lithography processing. There are typically both wet and dry processing chambers within track lithography tools. Wet chambers include coat and/or develop bowls, while dry chambers include thermal control units that house bake and/or chill plates. Track lithography tools also frequently include one or more pod/cassette mounting devices, such as an industry standard FOUP (front opening unified pod), to receive substrates from and return substrates to the clean room, multiple substrate transfer robots to transfer substrates between the various chambers/stations of the track tool and an interface that allows the tool to be operatively coupled to a lithography exposure tool in order to transfer substrates into the exposure tool and receive substrates from the exposure tool after the substrates are processed within the exposure tool.

FIG. 1 is a simplified flow diagram illustrating a series of process steps in a conventional process flow. As illustrated in FIG. 1, a series of process modules P₁ through P₆ are utilized to perform a series of particular process steps on one or more wafers or substrates. In the process steps illustrated in FIG. 1, a robot R₁ transfers a wafer from pod 110 to process chamber P₁. After a process step is performed using process chamber P₁, the wafer is transferred to process chamber P₂ using robot R₂. As illustrated in the figure, the series of process steps is carried out as the wafer is moved through processing chambers P₁ through P₆ by robots R₁ through R₃ until the wafer is transferred back to pod 110.

As further illustrated in FIG. 1, a series of process steps or sequences, S₀ through S₈ are associated with each of the pods and processing chambers. Generally, a series of processing steps are combined to form a recipe, which defines the processing history of a substrate passing through the track lithography tool. Each processing sequence or step S₁ through S₇ typically is defined by a process time along with various processing parameters associated with a particular processing chamber. In the flow diagram illustrated in FIG. 1, robots R₁ through R₃ serve multiple process chambers. As an example, robot R₂ serves processing chambers P₁, P₂, P₃, P₅, and P₆.

FIG. 2 is a simplified flow diagram illustrating a series of process steps performed in multiple process chambers in another conventional process flow. In order to reach a desired system throughput, in some track lithography tools, multiple process chambers are provided to perform a particular process step. Merely by way of example, two process chambers P₁₁ and P₁₂ are provided to perform process P₁ on wafers passing through the track lithography tool.

In general, as described above, a wafer W (also referred to as a substrate) is processed through a series of sequence steps Sᵢ, where i equals 0, 1, . . . , k, representing the process recipe and where k is the number of sequencing steps that are required before wafer W is completely processed by the cluster tool, which is a track lithography tool in an embodiment according to the present invention. Additionally, the beginning step (e.g., the pod) is denoted S₀ and the final step (e.g., also a pod) as Sₖ₊₁. In general, at each of the sequencing steps, wafer W may be processed by one of a number of parallel-oriented process chambers collectively denoted by Pᵢ. As an example, chambers Pᵢ₁ and Pᵢ₂ may both perform the same process such that either one of the chambers can be used to fulfill a given sequence step Sᵢ. The notation tᵢ is used to denote the processing time required to process wafer W in any chamber Pᵢⱼ within the chamber group Pᵢ during the sequence step Sᵢ. The variable j identifies the chambers within the group Pᵢ that can fulfill the sequence step Sᵢ.

For example, consider the series:

POD→(P₁₁ or P₁₂)→(P₂₁ or P₂₂)→POD

In this configuration, k equals 2, S₀ and S₃ are the FOUPS or Pods, chambers P₁₁ and P₁₂ can fulfill sequence step S₁, and chambers P₂₁ and P₂₂ can fulfill sequence step S₂. This sequence is schematically depicted as a portion of a wafer flow diagram (also known as a wafer flow graph) in FIG. 2. As such, a number of traces can be used to fulfill the process sequence S₀ through S₃ such as:

POD→P₁₁→P₂₁→POD

POD→P₁₁→P₂₂→POD

POD→P₁₂→P₂₁→POD

POD→P₁₂→P₂₂→POD

This nomenclature shall be used in describing the various embodiments of the invention described below.

Depending on the time required for each process step, more process chambers may be provided (e.g., P₅₁ through P₅₃) or fewer process chambers may be provided (e.g. P₄). As illustrated in FIG. 2, two arrows are illustrated between the pod 210 and the multiple process chambers P₁₁ and P₁₂, as the robot R₁ is able to transfer the wafer from the pod to any of the process chambers P₁ⱼ. In a similar manner, robot R₂ is generally able to transfer wafers from any of process chambers P₁ⱼ to any of process chambers P₂ⱼ.

Over the years there has been a strong push within the semiconductor industry to shrink the size of semiconductor devices. The reduced feature sizes have caused the industry's tolerance to process variability to shrink, which in turn, has resulted in semiconductor manufacturing specifications having more stringent requirements for process uniformity and repeatability. An important factor in minimizing process variability during track lithography processing sequences is to ensure that substrates processed within the chambers of the track lithography tool undergo repeatable processing steps. Thus, process engineers will typically monitor and control the device fabrication processes to ensure repeatability from substrate to substrate.

One approach to providing repeatability is to perform processing steps for a predetermined time. However, given the numerous paths different substrates can take as they move through a track lithography tool, with transfer steps being performed by multiple robots, performing processing steps for a predetermined time may not ensure the desired process repeatability. Ultimately, time-varying process parameters may directly affect process variability and ultimately device performance.

In view of these requirements, methods and apparatus are needed to ensure process repeatability during semiconductor processing operations using track lithography and other types of cluster tools.

### SUMMARY OF THE INVENTION

According to the present invention, techniques related to the field of substrate processing equipment are provided. More particularly, the present invention relates to a method and apparatus for transferring substrates during processing in a track lithography tool. Merely by way of example, the invention has been applied to dynamically adjust a wafer transfer decision in real-time as wafers move through a multi-chamber track lithography tool. The method and apparatus can be applied to other processes for semiconductor substrates, for example those used in the formation of integrated circuits.

In an embodiment according to the present invention, a method of operating a track lithography tool is provided. The track lithography tool is adapted to process a plurality of substrates according to a recipe, the recipe including a plurality of process steps and a plurality of transfer steps. The method includes determining a process time associated with a time critical process and determining an initial sending rate for the track lithography tool. In a particular embodiment, the time critical process is a transfer time between a photolithographic exposure process and a subsequent post exposure bake process.

The method also includes transferring at least one of a plurality of wafers into the track lithography tool at the initial sending rate and monitoring a variation in the process time associated with the time critical process. In some embodiments, the variation in the process time is an increase in the process time. The method further includes increasing the duration of at least one of the plurality of process steps, wherein the duration of the at least one of the plurality of process steps is increased by an amount equal to the variation in the process time associated with the time critical process.

In an alternative embodiment according to the present invention, a method of operating a cluster tool is provided. The method includes determining a first process step of a recipe. The recipe is associated with a first substrate moving through the cluster tool. The first process step is associated with a first process time. The method also includes determining a second process step of the recipe. The second process step is associated with a second process time. Moreover, the second process step is a critical process step. In a specific embodiment, the time critical process is a transfer time between a photolithographic exposure process and a subsequent post exposure bake process.

The method further includes monitoring a duration of the second process step and detecting a variation in the duration of the second process step. The method additionally includes increasing a duration of the first process step in response to detecting a variation in the duration of the second process step. In some embodiments, the increase in duration of the first process step is substantially equal to the variation in the duration of the second process step. In another specific embodiment, the method further includes determining a third process step of the recipe, decreasing the duration of the first process step, and increasing a duration of the third process step, wherein the increase in the duration of the third process step is substantially equal to the decrease in duration of the first process step.

In another embodiment according to the present invention, a computer readable medium storing a number of instructions for controlling a data processor to operate a semiconductor wafer cluster tool is provided. The number of instructions include instructions that cause the data processor to determine a first process step of a recipe. The recipe is associated with a first substrate moving through the cluster tool and the first process step is associated with a first process time. The number of instructions also include instructions that cause the data processor to determine a second process step of the recipe. The second process step is associated with a second process time and the second process step is a critical process step. The number of instructions further include instructions that cause the data processor to monitor a duration of the second process step and instructions that cause the data processor to detect a variation in the duration of the second process step. The number of instructions additionally include instructions that cause the data processor to increase a duration of the first process step in response to detecting a variation in the duration of the second process step. In an embodiment, the increase in duration of the first process step is substantially equal to the variation in the duration of the second process step.

In yet another embodiment of the present invention, a method of processing a plurality of substrates according to a recipe is provided. The recipe includes a plurality of process steps, a plurality of transfer steps, and one or more delay steps. The method includes determining a fundamental period for the processing of the plurality of substrates and transferring the plurality of substrates into a track lithography tool at the fundamental period. The method also includes monitoring a variation in the process time associated with at least one of the plurality of process steps or the plurality of transfer steps and increasing the duration of at least one of the one or more delay steps to compensate for the variation in the process time. In a specific embodiment, the variation in the process time includes an increase in the process time and the duration of the at least one of the one or more delay steps is increased by a time equal to the variation in the process time.

Many benefits are achieved by way of the present invention over conventional techniques. For example, an embodiment provides a more repeatable wafer history than conventional designs, resulting in improved control over critical dimensions. Moreover, other embodiments of the present invention provide methods and systems adapted to shift process and transferred delays to process steps that minimize process variations. Additionally, alternative embodiments of the present invention provide recipe time adjustments and cassette delay adjustments or combinations thereof that improve wafer to wafer repeatability. Depending upon the embodiment, one or more of these benefits, as well as other benefits, may be achieved. These and other benefits will be described in more detail throughout the present specification and more particularly below in conjunction with the following drawings.

### BRIEF DESCRIPTION OF THE DRAWINGS

FIG. 1 is a simplified flow diagram illustrating a series of process steps in a conventional process flow;

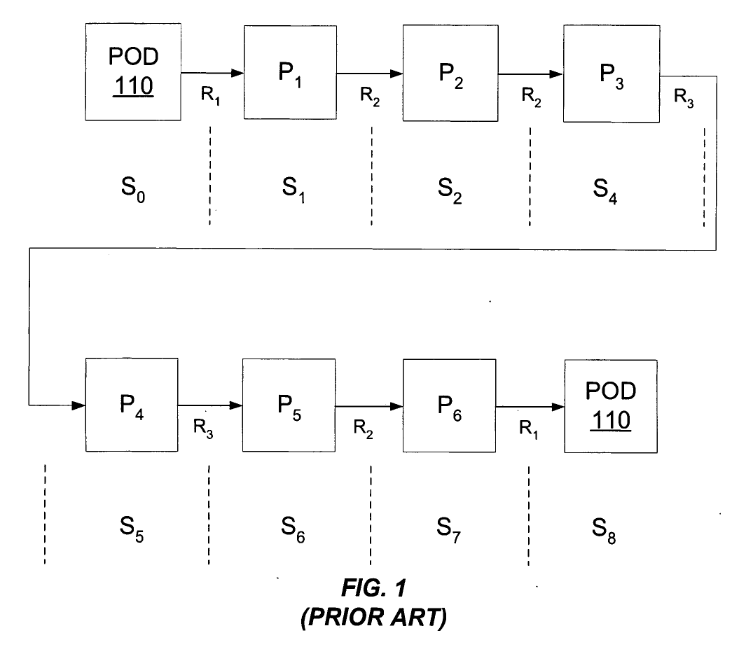

FIG. 2 is a simplified flow diagram illustrating a series of process steps performed in multiple process chambers in another conventional process flow;

FIG. 3A is a simplified flowchart illustrating a process flow according to an embodiment of the present invention;

FIG. 3B is a simplified flow diagram illustrating a process flow according to an embodiment of the present invention;

FIG. 4 is a simplified block diagram of a sequencer that performs operative steps in accordance with an embodiment of the present invention;

FIG. 5 is a simplified recipe diagram according to an embodiment of the present invention;

FIG. 6 is a chart illustrating an exemplary process flow according to an embodiment of the present invention; and

FIG. 7 is a simplified recipe diagram according to another embodiment of the present invention.

### DETAILED DESCRIPTION OF SPECIFIC EMBODIMENTS

According to the present invention, techniques related to the field of substrate processing equipment are provided. More particularly, the present invention relates to a method and apparatus for transferring substrates during processing in a track lithography tool. Merely by way of example, the invention has been applied to dynamically adjust a wafer transfer decision in real-time as wafers move through a multi-chamber track lithography tool. The method and apparatus can be applied to other processes for semiconductor substrates, for example those used in the formation of integrated circuits.

The inventors have noted that inconsistencies in wafer history are caused by several factors. One of these factors is process recipe variations due to end-point control. These process variations may be present, even for the same chamber. Additional process recipe variations are due to calibration inconsistency, hardware device performance variation, and the like. In applications for which there are multiple chambers dedicated to the same process step, the “chamber matching” issue will be reflected as wafer history differences.

Other factors resulting in inconsistencies in the wafer history include transfer time variations due the transfer path differences. For example, if the same robot serves the transfer between two consecutive process steps, and there are multiple chambers dedicated to each step; the transfer time will be dependent on the geometrical location of each chamber and the corresponding robot motion for that path. Moreover, robot sharing conflicts due to inappropriate scheduling and sequencing control the transfer tasks. For instance, in cluster tools, one robot is typically shared by multiple process steps depending on the topology of the cluster tool. The robot sharing conflict will not only contribute to the wafer history inconsistency but will also reduce the throughput of the system. For track lithography tool systems, any track-side reduction in throughput will effect the scanner utilization ratio.

For some process steps, the importance of providing timing consistency between process steps is greater than other steps in the fabrication process. Merely by way of example, thermal, wet coating, and exposure processes are timing dependent because the wafer properties may be changing after the completion of a current process recipe. Some integrated processes (e.g., Track, ECP, high-κ gate, multi-layer metal deposition, and the like) require consistent wafer timing control to achieve repeatable process results on production wafers. Thus, it is generally believed that timing consistency is not only a system throughput issue, but rather a “must-have” requirement for many cluster tool systems (both hardware and software) to realize these time sensitive integrated processes. Modifying hardware (e.g., adding more robots, changing the chamber design) is typically more expensive, limited by space, and less flexible for all process requirements than modifying just software. Thus, methods and techniques related to software sequencers are playing increasingly important roles in providing solutions to the aforementioned problems.

According to embodiments of the present invention, methods and systems are provided to maximize the utilization of the chamber resources to schedule the maximum delay for each process step to maximize the tolerance for the process and transfer variations without affecting overall system throughput. Monitoring the process and transfer variations in real-time, delay designed into the process flow or recipe is adjusted to absorb variations, and hence achieve the desired wafer history consistency.

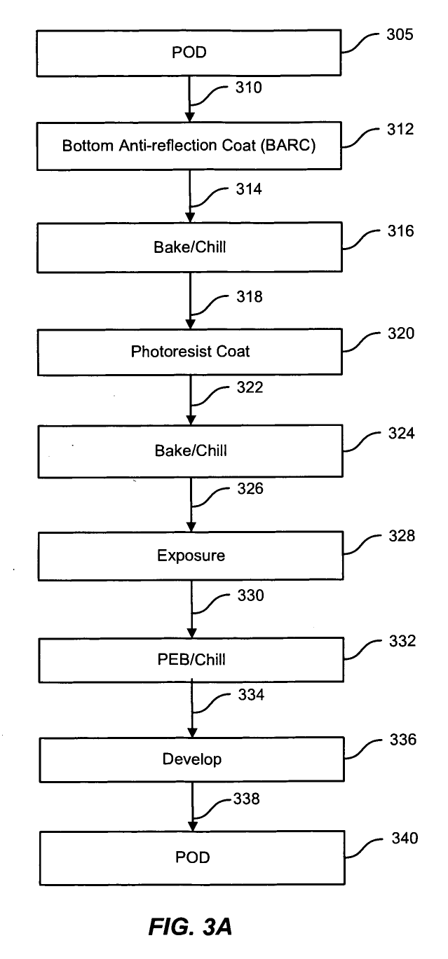

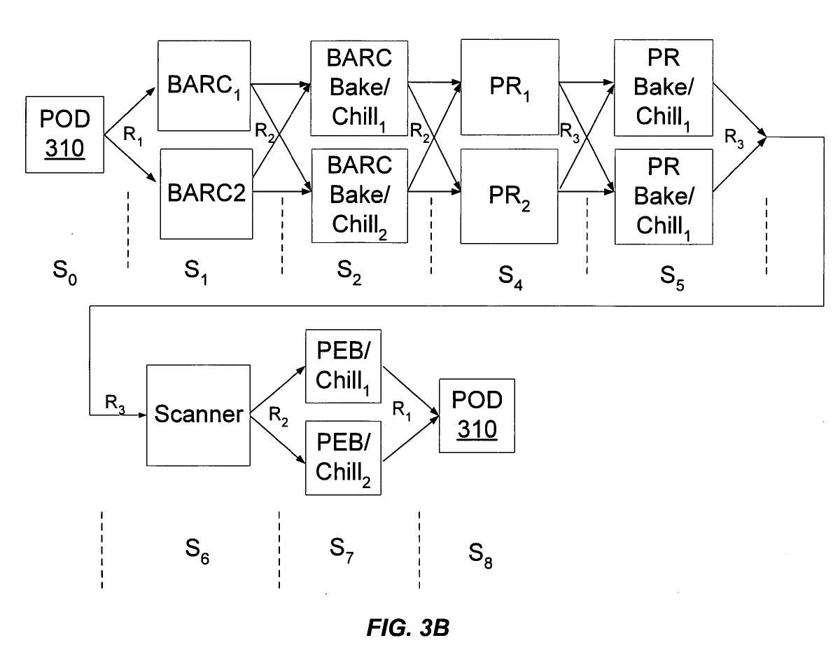

FIG. 3A is a simplified flowchart illustrating a process flow 300 according to an embodiment of the present invention. In transfer step 310, a substrate or wafer is transferred from a FOUP or Pod (305) to a first process tool adapted to perform a bottom antireflection coating (BARC) step. The various process tools described herein may also be referred to as process chambers. In some embodiments, as described above, the cassette associated with the initial stage of transfer step 310 is referred to as a FOUP or Pod. In the embodiment illustrated in FIG. 3A, the first process chamber is a spin module adapted to perform a BARC process (312). The transfer time between the FOUP or Pod and the first process chamber is not illustrated in FIG. 3A, but it will be evident to one of skill in the art that a transfer time is included between process steps. In the BARC process (312), the BARC is applied during a processing time of 45 seconds. Depending on the particular BARC applied, the processing time may vary. The particular coating illustrated in BARC process (312) is merely illustrative, and one of skill in the art will appreciate that other processing times associated with other processing steps are included within embodiments of the present invention.

The substrate is transferred from the BARC chamber to a bake/chill chamber in transfer step 314. The substrate is baked and chilled at selected predetermined temperatures for a combined time period of 90 seconds during Bake/Chill process (316). As will be evident to one of skill in the art, the times and temperatures appropriate for this post-BARC bake/chill process will depend on the particular coating. In transfer step 318, the substrate is transferred from the bake/chill chamber to a spin module adapted to perform a photoresist (PR) coat process (320). In the embodiment illustrated in FIG. 3A, the PR coat process (320) is a 40 second process.

After the PR coat process (320) is completed, the substrate is transferred to a bake/chill chamber in transfer step 322, where the PR coating undergoes a Bake/Chill process (324) for a combined time of 90 seconds. In some embodiments, the bake/chill chamber utilized for the post-BARC bake process and the post-PR coat bake process is a common chamber, whereas in alternative embodiments, different chambers are utilized for the different steps. Moreover, in some embodiments, the temperatures utilized for the various bake plates are the same or differ depending on application.

The substrate is transferred in transfer step 326 to a scanner for exposure of the photoresist during an exposure process (328). In some embodiments, the exposure time is 5 seconds, although this not required by the present invention. After exposure, the substrate is transferred in transfer step 330 to a module adapted to perform a post exposure bake/chill (PEB/Chill) process (332). In some semiconductor processes, the time between the exposure process (328) and the PEB/Chill process (332) is a critical time process. These processes are sometimes referred to as queue time constrained processes, as the substrate is preferably transferred to the next process module within a period referred to as a maximum queue time. In some embodiments, if the maximum queue time is exceeded after a wafer completes the critical process step, it is preferable to provide the same queue time behavior for all wafers in a given lot.

In other applications, these processes are referred to as critical time processes, as the time between the beginning and/or ending of a first process and the beginning and/or ending of a subsequent process is preferably uniform from substrate to substrate. In particular, linewidths and critical dimensions may be dependent on the time between the exposure step and the PEB/Chill process. The substrate is transferred to a develop chamber in transfer step 334, the pattern exposed in exposure process (328) is developed during a develop process (336), and the substrate is transferred in transfer step 338 to the FOUP or Pod (340).

The process illustrated above is merely an exemplary process for a track lithography system it is not intended to limit embodiments of the present invention. In alternative embodiments, the number of steps, the order of the steps, and the lengths of the various steps are modified depending on the particular application. Other alternatives can also be provided where steps are added, one or more steps are removed, or one or more steps are provided in a different sequence without departing from the scope of the claims herein. Further details of the process recipes or flows can be found throughout the present specification and more particularly below.

FIG. 3B is a simplified flow diagram illustrating a process flow according to an embodiment of the present invention. As illustrated in FIG. 3B, two processing chambers BARC₁ and BARC₂ are provided to perform the BARC step described in relation to FIG. 3A. Robot R₁ transfers substrates from the Pod 310 to the respective BARC chambers. As will be evident to one of skill in the art, the substrates are generally staggered as they are loaded into the BARC chambers by robot R₁. After formation of the BARC, robot R₂ is used to transfer the substrates to the post-BARC bake/chill chambers. Depending on chamber availability, among other factors, either of chambers BARC Bake/Chill, or BARC Bake/Chill₂ are utilized. Although two BARC chambers are illustrated in FIG. 3B, this is not required by the present invention. In some embodiments, additional chambers and/or robots are provided as appropriate to the particular application. In general, the number of chambers provided is a function of the processing times associated with a particular set of chambers and the desired wafer throughput.

Multiple photoresist chambers PR₁ and PR₂ are provided in the process flow illustrated in FIG. 3B, along with multiple PR Bake/Chill chambers, serviced by robots R₂ and R₃. A single scanner is provided for the exposure step, followed by multiple PEB/chill chambers, after which the substrates are transferred to the FOUP in the final Pod step.

As illustrated in the process flow described with respect to FIGS. 3A and 3B, in some track lithography tools, multiple process chambers are dedicated to perform the same type of process step. For example, in the previously illustrated process flow, multiple BARC, bake/chill, and photoresist chambers are provided. Although this architecture may provide increased throughput, in some systems, the process time for a given recipe performed in different process chambers may be different due to the mismatch between the different process chambers.

Merely by way of example, the mismatch may result from differences in calibration, performance, and/or assembly steps associated with the particular process chambers. For instance, in track lithography tools with multiple bake/chill chambers, the calibration of the bake or chill plates may differ, resulting in bake or chill processes characterized by differing times. Moreover, depending on the process recipe, module performance parameters may result in recipe mismatch. Merely by way of example, in a bake process that monitors the bake plate temperature, integrating the bake temperature and utilizing the temperature time product to determine an endpoint, differing bake plate temperatures will generally result in differing process times.

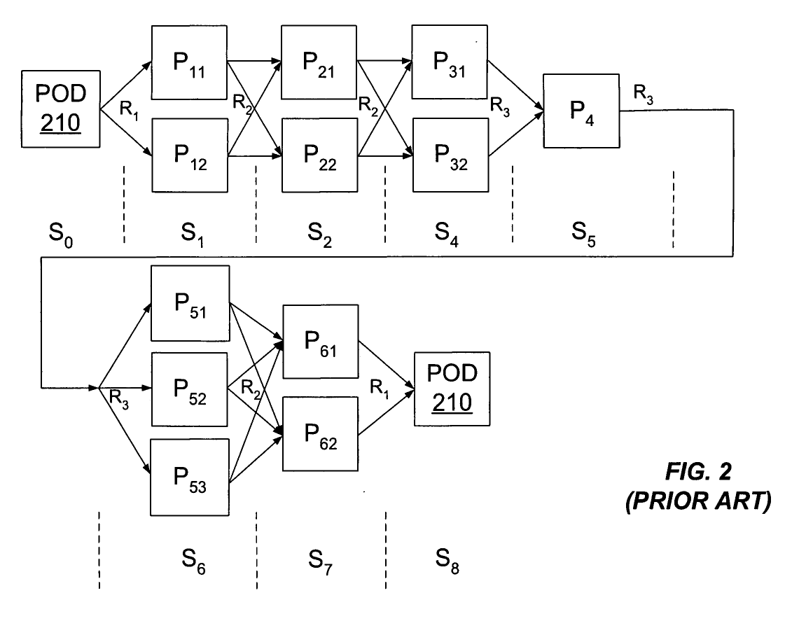

Additionally, in track lithography tools utilizing multiple process chambers to perform the same type of process step, transfer delays may depend on the particular series of chambers utilized in processing a particular substrate. For example, referring to FIG. 2, a transfer from process chamber P₁₁ to process chamber P₂₂ may require more time than a transfer from process chamber P₁₁ to process chamber P₂₁. As an example, many tracks lithography tools provide multiple process chambers in a vertically stacked architecture. In these tools with vertically stacked chambers, the time used for a robot to transfer a substrate from a chamber near the top of the stack to another chamber near the top of the stack may differ from the time required to transfer the substrate from a chamber near the top of the stack to another chamber near the bottom of the stack. Based on these examples, one of ordinary skill in the art will thus appreciate the differing transfer times associated with some track lithography tools.

Moreover, in addition to process variations resulting from the use of multiple process modules and the transfers between such modules, the actual process time may vary for a single process module due to the control of the process recipe execution. For example, if a particular process recipe contains an endpoint controlled step, the endpoint condition may be different from wafer to wafer. Merely by way of example, an endpoint detection process could be based on temperature, pressure, motor speed and the like. Referring once again to the example process flow provided in FIGS. 3A and 3B, the BARC and/or PR coating steps may be terminated by an endpoint detection process, for example, when the coating layer reaching a predetermined thickness. Depending on the spin rate of the spin chuck, the viscosity of the liquid used to form the layer, and the like, the time utilized to reach the predetermined thickness may vary. One of ordinary skill in the art will appreciate similar time variations associated with endpoint controlled bake and chill steps. Therefore, the actual time spent performing this recipe step may vary, thereby resulting in variation of the total process time for a wafer in a lot of wafers.

Furthermore, in some cluster tools, both cyclical and noncyclical cleaning processes may introduce delays as wafers move through the cluster tool. For example, in some coat bowls utilized in track lithography tools, periodic cleaning processes are utilized to remove excess coating material. These cyclical cleaning processes may impede the flow of wafers through the track lithography tool as a function of time. Additionally, coat bowls or other process modules may undergo non-periodic cleaning processes initiated by detection of a predetermined condition. Merely by way of example, a sensor may detect the collection of a liquid that is preferably drained when the liquid level reaches a selected level. Depending on the particular recipes utilized during processing, this collection/draining process may be performed on a non-periodic basis. Accordingly, delays may be introduced due to these cleaning processes.

One of skill in the art will appreciate that for a track lithography tool, calculations may be performed to determine robot service intervals. For example, the time (tNeedTransfer[i]) at which a process module for a given process step [i] is provided with robot service can be statically calculated by the following algorithm illustrated by pseudocode:

tNeedTransfer[i] = 0;
For (k = 2; k <= i; k++)
{
− tNeedTransfer[i] = tNeedTransfer[i] + Tk + Pk
}
tNeedTransfer[i] = tNeedTransfer[i] mod FP,

where Tk is the transfer time, Pk is the process time, and FP is the fundamental period (FP) of the system corresponding to the target throughput. In performing this calculation, several assumptions are made. These assumptions include assuming that step 1 is always from a loadport or Pod; that there is no time variation for wafer transfer and processing; that the scheduler will perform a wafer transfer whenever there is an available process module available for the next process step; that the robot is available; and that every FP there will a wafer sent from the loadport.

According to embodiments of the present invention, methods and systems are provided to maximize the utilization of the chamber resources to schedule the maximum delay for each process step to maximize the tolerance for the process and transfer variations without affecting overall system throughput. Monitoring the process and transfer variations in real-time, delay designed into the process flow or recipe is adjusted to absorb variations, and hence achieve the desired wafer history consistency.

According to a particular embodiment of the present invention, the method includes using an algorithm to calculate the desired delays for each process step. In an embodiment, the algorithm is illustrated by the following pseudocode:

tNeedTransfer[i] = 0;
For (k = 2; k <= i; k++)
{
− tNeedTransfer[i] = tNeedTransfer[i] + Tk + Pk + Dk
}
tNeedTransfer[i] = tNeedTransfer[i] mod FP,

Assuming there are N[i] process modules dedicated to sequence step i, thus the fundamental period for the chamber itself is:
FP[i]=(2*T[i]+P[i])/N[i].
For the target FP, the maximum delay the step i can have is:
Max_{—}D[i]=FP*N[i]−P[i]−2*T[i].
If Max_D[i]<0, this means that step [i] is a bottle-neck step and adding extra delay will further reduce or downgrade the throughput. For the non-bottle-neck and non-critical steps, Max_D[i] gives a maximum possible delay without affecting the system throughput.

After we have a vector of tNeedTransfer[i], i=1 . . . N, where N is the number of sequence steps, an algorithm is used to calculate the vector of D[i], i=1 . . . N, where N is the number of sequence steps. Accordingly, this method provides that tNeedTransfer[i]+T[i, i+1] will not overlap with any other tNeedTransfera[j]j< >i.

In some embodiments of the present invention, the algorithm will put priority in finding the maximum value of a number of values of D[i] for the non-critical, non bottle-neck steps which satisfy D[i]<=Max_D[i] and there is no transfer conflict.

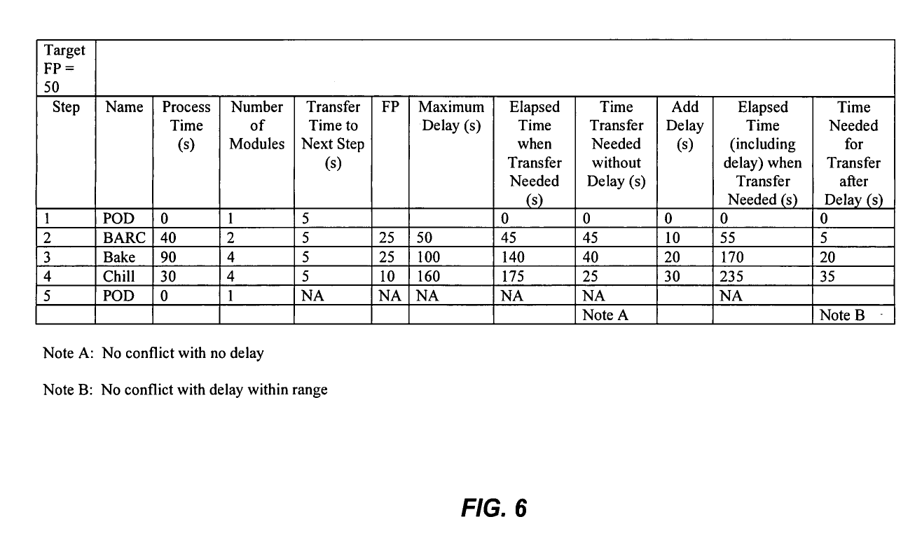

As an example, FIG. 6 is a chart illustrating an exemplary process flow according to an embodiment of the present invention. In the process flow illustrated in FIG. 6, the target FP is 50 wafers per hour. Five process steps: POD, BARC, Bake, Chill, and POD are shown in FIG. 6. For the same target FP, although there is no transfer conflict without any inserted delay, each process step still could have some delays which satisfy the condition D[i]<Max_D[i] and there is no transfer conflict. For the immersion lithography process, it is most likely that the scanner will be the bottleneck module, enabling the track lithography tool to use time wisely and intentionally insert some delays without affect the throughput of the system. These delays will be used to absorb the possible process and transfer variations during the sequence execution.

According to another particular embodiment of the present invention, the method also includes using an algorithm to monitor the variations in process time and adjust the delay during run-time. During operation, each wafer will be introduced to the system every FP, so for wafer K, the expected time when the wafer will be transferred from process step i to step i+1 is:
Expected absolute transfer time=(K−1)*FP+tNeedTransfer[i].

Accordingly, the expected recipe completion time is:
(K−1)*FP+tNeedTransfer[i]−D[i].

Therefore, in an embodiment, logic is used to adjust the D[i] according to the actual recipe completion time. In an embodiment, this logic or algorithm is illustrated by the following pseudocode:

```
Void OnProcessRecipeCompleted( )
{
If (actual recipe completion time > expected recipe completion time)
{
    // if there is a latency when the recipe completed
    // reduce the D[i] to absorb the latency to maintain the original schedule
    D[i] = D[i] − (actual recipe completion time − expected recipe completion time);
    If (D[i] < 0)
        D[i] = 0; // normally it should not happen, only when there is a large variation
that is out of the scheduled range
}
else
{
    // if the recipe finished earlier than expected
    // increase the D[i] to keep the original schedule
    D[i] = D[i] + (expected recipe completion time − actual recipe completion time);
}
RunDelay(D[i])
}
```

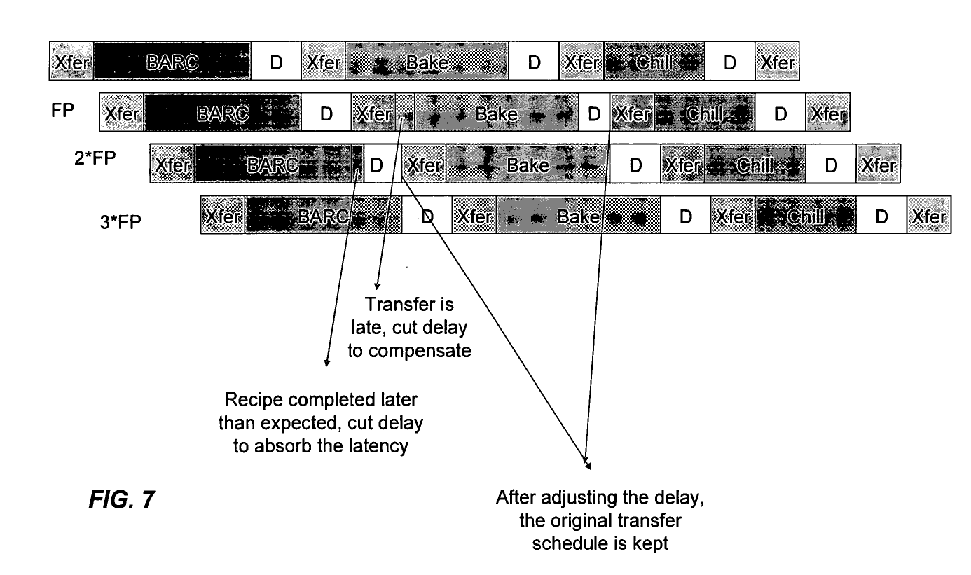

FIG. 7 is a simplified recipe diagram according to another embodiment of the present invention. As illustrated in FIG. 7, in this exemplary recipe diagram, the transfer from the BARC module to the Bake module is delayed for the second wafer. In response to this transfer delay, the scheduled delay after the Bake step is reduced to compensate for the late transfer. Referring to the third wafer, the BARC recipe is completed later than expected. As a result, the delay after the BARC step is reduced to absorb the latency. Note that after the delays are adjusted for wafers 2 and 3, the original transfer schedule is kept for processes subsequent to the adjusted delay.

In some embodiments of the present invention, the delay (Dk) is set to zero for one or more critical process steps. Setting the delay to zero may tend to result in an increase in the number of process chambers. As described above, transfer and processing variations are accounted for by algorithms provided herein.

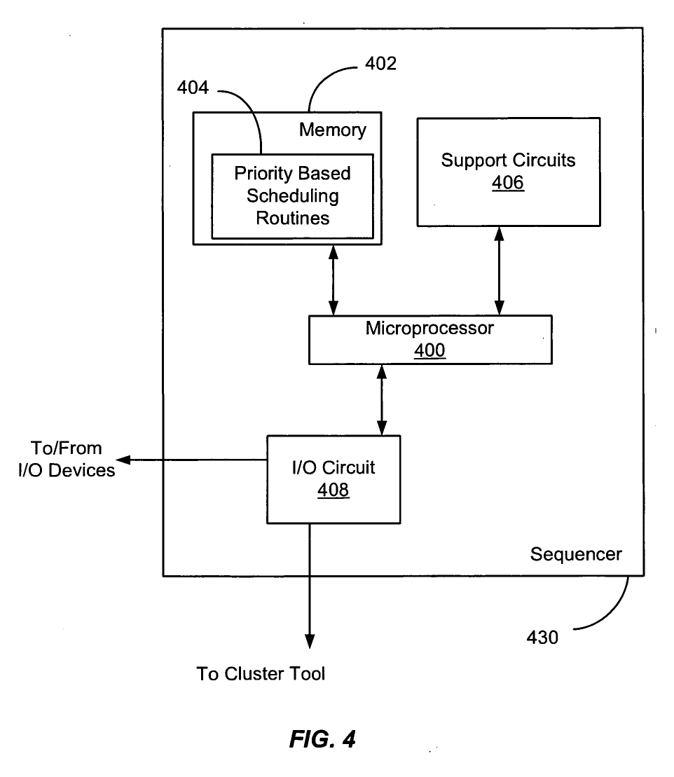

FIG. 4 depicts a block diagram of a sequencer that operates to control the processing and wafer transfer processes performed by a cluster tool according to an embodiment of the present invention. The sequencer 430 contains a microprocessor 400, a memory 402 for storing the routines of the present invention, and support circuits 406, such as power supplies, clock circuits, cache and the like. The sequencer 430 also contains input/output circuitry 408 that forms an interface between conventional input/output (I/O) devices such as a keyboard, mouse, and display, as well as an interface to the track lithography tool. In an embodiment, the sequencer 430 is a general purpose computer that is programmed to perform the sequencing and scheduling operations in accordance with the present invention. The software implementation 404 of the methods of the present invention are stored within memory 402 and executed by the microprocessor 400 to facilitate control of at least one robot wafer transport mechanism within the track lithography tool.

It is contemplated that some of the process steps discussed herein as software processes may be implemented within hardware, e.g., as circuitry that cooperates with the microprocessor to perform various process steps. Although the schedule generator is depicted as a general purpose computer that is programmed to perform the scheduling routines in accordance with the present invention, the invention can be implemented in hardware as an application specific integrated circuit (ASIC). As such, the process steps described herein are intended to be broadly interpreted as being equivalently performed by software, hardware, or a combination thereof.

In typical track lithography tools, in addition to the processing or recipe time variations described above, additional time variation results from variations in scanner times. For example, in some scanners, the alignment and focusing operations performed in the scanner may vary from wafer to wafer. Moreover, adjustment procedures performed by the scanner, such as maintenance of optical sources, may be performed before, during, or after the processing of wafers, introducing variations in scanning times. These operations and procedures may result in differing times from one wafer to the next for the period from exposure to post-exposure bake. Merely by way of example, the variations in processing times in the scanner may exceed the typical cycle time of a wafer being processed by the scanner. In the example recipe illustrated in FIG. 3A, the processing time in the scanner is only five seconds. Accordingly, relatively short delays, in comparison with other illustrated process steps, may result in variations in the scanner processing time exceeding the typical cycle time of wafers through the scanner.

In an embodiment according to the present invention, methods and apparatus are provided to absorb variations locally (at a particular process step [i]), so that the variations do not propagate downstream to subsequent processing steps. In a particular embodiment, scanner variations are absorbed upstream of the scanner at processing steps where variations do not impact wafer to wafer repeatability. Accordingly, in an embodiment of the present invention, a method is provided in which a feeding rate to selected downstream process steps is monitored and maintained to achieve a uniform wafer history at critical process steps.

In an embodiment, a process flow is analyzed to determine a first process time associated with a time critical process. In a specific embodiment, the first process time is the length of time required for a “bottleneck” process, which is a process that entails a longer time period than any other process sequence performed on the wafer, normalized by the number of process chambers dedicated to perform the process. As will be evident to one of skill in the art, the bottleneck process may be a process that is not the process that utilizes the longest time period, but a shorter process for which a fewer number of process chambers are provided. In some embodiments, the first process time, equal to the time period for the process divided by the number of process chambers dedicated to perform the process is used to define a fundamental period for the cluster tool. The rate at which substrates are sent into the cluster tool (a sending rate) is initially set at a value equal to this fundamental period.

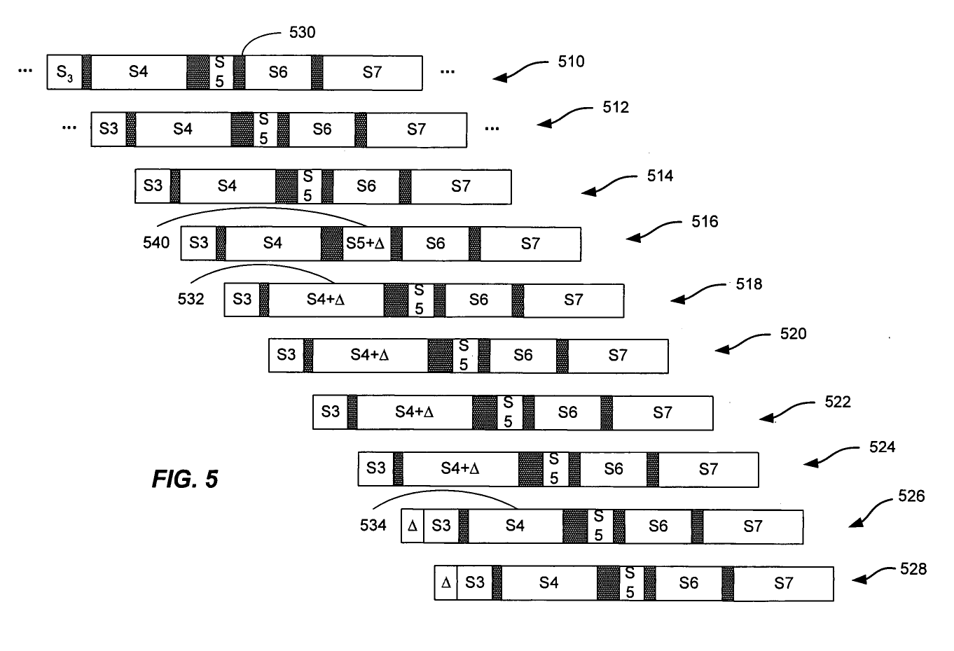

FIG. 5 is a simplified recipe diagram according to an embodiment of the present invention. As illustrated in FIG. 5, only a subset of a particular process flow is described. This abridged version of the process flow is provided merely for illustrative reasons, and is not intended to limit embodiments of the present invention to these particular process steps. In FIG. 5, the process steps of PR coat (S₃), PR bake/chill (S₄), exposure (S₅), PEB/chill (S₆) and develop (S₇) are illustrated. For purposes of clarity, additional steps prior to S₃ and subsequent to S₇ are omitted and illustrated by the ellipses in front of S₃ and behind S₇ in recipes 510 and 512. One of ordinary skill in the art will appreciate that embodiments of the present invention are not limited to these particular steps, but include additional steps as well as steps performed in alternative sequences.

In general, a process recipe will specify, among other parameters, the process times, temperatures, etc. and the transport tasks for each task performed on the substrate as the substrate moves through the track lithography tool. As will be evident to one of skill in the art, embodiments of the present invention are not limited to track lithography tools, but are also applicable to a variety of cluster tools, including those used for physical vapor deposition (PVD), chemical vapor deposition (CVD), and the like. Merely by way of example, embodiments of the present invention are applicable to a series of recipes staggered in time as illustrated in FIG. 5. Recipe 510 is associated with a first substrate W₁ and recipe 512 is associated with a second substrate W₂. Subsequent recipes are associated with subsequent substrates and are initially staggered by the sending rate.

Transfer tasks are illustrated by the darkened regions between adjacent process steps and, as illustrated by transfer task 530, may vary in length. As will be evident to one of skill in the art with reference to FIGS. 3A and 3B, various robots are utilized according to embodiments of the present invention. Accordingly, transfer times may depend not only on the process chambers, but the robots utilized to perform the transfers as well. Of course, as discussed above, variations in process time from chamber to chamber, variations in transfer times between chambers, variations within a given chamber, and periodic and non-periodic cleaning processes, are accounted for by embodiments of the present invention but not illustrated in recipes 510 through 514.

Some track lithography tool recipes are characterized by time critical processes, for example the time between exposure of the substrate and the initiation of post exposure bake/chill process. Therefore, embodiments of the present invention provide methods and systems to sequence wafers, maintaining uniform wafer to wafer times for these time critical processes. In the series of recipes illustrated in FIG. 5, transfer task 530 is such a time critical process, illustrating the transfer between the exposure process (S₅) and the PEB/chill step (S₆).

In the series of recipes 510 through 528 illustrated in FIG. 5, substrates are loaded into the cluster tool, initially reaching process S3 in a periodic fashion. For the first three wafers, recipes 510, 512, and 514 are executed without significant delays. Accordingly, each of these wafers W₁ through W₃, exit the cluster tool at the pod after the steps following step S₇ (not illustrated). However, during the processing of substrate W₄ using recipe 516, the exposure step S₅ is not performed in the regular period, but is delayed by an additional time Δ, resulting in a scanner time of S₅+Δ. As will be evident to one of skill in the art, this delay during the exposure process may result from a variety of factors, including refocusing of the scanner optics, repositioning of the substrate within the scanner, recentering of the substrate, and the like. This delayed exposure step is illustrated by process 540.

In some embodiments according to the present invention, this delay is referred to as a recipe time adjustment. When the delay Δ is detected by the system sequencer, an additional delay equal to the delay Δ in the exposure process is introduced at the PR bake/chill step (S₄) for the subsequent substrate W₅. This additional delay, Δ, is illustrated at process 532. In some embodiments according to the present invention, the delay is introduced at the end of the bake/chill step S₄, while the wafer W₅ is located on a chill plate. Generally, when a wafer is positioned on a chill plate following the completion of the typical chill process, additional delay does not significantly impact process parameters. These process parameters may include linewidths, critical dimensions, process uniformity, processed repeatability, and the like.

As illustrated in recipe 518 of FIG. 5, the addition of the delay to wafer W₅ at step S₄, enables a delayed transfer for wafer W₅ to the exposure chamber, preserving a uniform time between the exposure step S₅ in recipe 518 and the PEB/chill step S₆ in recipe 518. Additional delays equal to Δ are introduced during the PR bake/chill step (S₄) for substrates W₆, W₇, and W₈ as illustrated by recipes 520, 522, and 524, respectively. In some embodiments, the delays are introduced while the respective wafer is positioned on the chill plate.

In recipe 526, an additional delay Δ is introduced prior to the beginning of process S₃. In some embodiments according to the present invention, the delay illustrated in recipe 526 and 528 is referred to as a cassette delay adjustment. As will be evident to one of skill in the art, the time at which recipe 526 reaches step S₃, is aligned with or shortly after the time at which the delay was initially introduced into recipe 516 by the scanner delay. Accordingly, the delay is removed from the S₄ process and introduced prior to the S₃ process. As will be evident to one of skill in the art, the delay may be shifted to steps earlier than S₃ as time progresses. Although not illustrated in FIG. 5 for purposes of clarity, in some embodiments of the present invention, the delay is subsequently shifted to a time prior to step S₁ for one or more subsequent wafers.

As illustrated in FIG. 5, recipes 526 and 528 are performed without introducing delays into steps S₃ through S₇. Utilizing embodiments of the present invention, all the recipes from 510 through 528 provide a uniform time between the end of the exposure step (S₅) and the beginning of the PEB/chill step (S₆), providing the desired process uniformity for this critical step. In some embodiments, recipe time adjustments are converted into cassette delay adjustments as subsequent wafers move through the cluster tool. Of course, recipe time adjustments and cassette delay adjustments may be provided to account for variations in process steps and transfers in addition to the period between the end of the exposure step and the beginning of the PEB/chill step.

Embodiments of the present invention provide methods and systems adapted to monitor, detect, and account for delays experienced in processes throughout the cluster tool. For example, multiple delays may be summed and combined as part of the method to provide uniform wafer histories. Moreover, although not illustrated in FIG. 5, both recipe time adjustments and cassette delay adjustments may be present in one or more recipes. Accordingly, if an additional scanner delay Δ₂ was experienced in recipe 524, an additional delay period equal to Δ₂ may be added to process 534 during recipe 526. In this example, during recipe 526, the delay Δ the would be converted from a recipe time adjustment to a cassette delay adjustment, while the additional delay Δ₂ would remain in recipe 526 as a recipe time adjustment. As one of skill in the art will appreciate, in subsequent recipes, the additional delay Δ₂ could be converted to a cassette delay adjustment.

In some embodiments of the present invention, communication and feedback between the sequencer and the process chambers provided in the cluster tool are utilized to maintain time periods for critical process steps. In particular embodiments, communication and feedback between the sequencer and the scanner are provided to adjust the sending period of the substrates to the scanner once the delay has been noted by the scanner. Algorithms present in the sequencer or on other computers provided as a part of the cluster tool subsequently introduce delays equal to the scanner delay for wafers upstream from the scanner. In some embodiments, algorithms adapted to combine multiple delays are provided.

Embodiments of the present invention have been illustrated above with respect to a track lithography tool, however applications of embodiments of the present invention are not limited to track lithography tools. The methods and systems provided by embodiments of the present invention may also be applied to other cluster tools, including those used for PVD, CVD, electrochemical polishing (ECP), chemical mechanical polishing (CMP), etch, and the like. For example, in a PVD application, the time between deposition of subsequent layers is monitored and controlled utilizing embodiments of the present invention. Moreover, in an ECP application, which is a wet process, the various processing steps are typically time sensitive because of the chemical reactions occurring as part of the ECP process. Accordingly, embodiments of the present invention are utilized to monitor and control such time sensitive process flows.

Additionally, the embodiments described above have related to delays in a scanner, generally directed toward maintaining a uniform wafer history for the time between the exposure and PEB/chill step. However, other critical steps during substrate processing are included in embodiments of the present invention. These critical steps include, but are not limited to the time between photoresist coating and PR bake, BARC coating and BARC bake, and the like. As described throughout the present specification, in some embodiments, bake/chill chambers are utilized, with the bake process generally preceding the chill process.

As will be evident to one of skill in the art, the methods and systems provided by embodiments of the present invention will account for and correct for delays experienced throughout the cluster tool. Merely by way of example, delays associated with cleaning cycles, transfers from chamber to chamber, variations between process chambers performing the same process, variations within a process chamber from wafer to wafer, and the like are included according to embodiments of the present invention.

The examples and embodiments described herein are for illustrative purposes only. Various modifications or changes in light thereof will be suggested to persons skilled in the art and are to be included within the spirit and purview of this application and scope of the appended claims. It is not intended that the invention be limited, except as indicated by the appended claims.

What is claimed is:

1. A method of operating a track lithography tool adapted to process a plurality of substrates according to a recipe, the recipe including a plurality of process steps and a plurality of transfer steps, the method comprising:
determining a process time associated with a time critical process;
determining an initial sending rate for the track lithography tool;
transferring at least one of the plurality of substrates into the track lithography tool at the initial sending rate;
monitoring a variation in the process time associated with the time critical process; and
increasing the duration of at least one of the plurality of process steps, wherein the duration of the at least one of the plurality of process steps is increased by an amount equal to the variation in the process time associated with the time critical process.

2. The method of claim 1 wherein the sending rate is equal to a time period associated with a process step divided by a number of process modules dedicated to perform the process step.

3. The method of claim 1 wherein the variation in the process time comprises an increase in the process time.

4. The method of claim 1 wherein the at least one of the plurality of process steps precedes the time critical process in the wafer recipe.

5. The method of claim 4 wherein the at least one of the plurality of process steps comprises a chill process.

6. The method of claim 1 wherein the time critical process comprises a transfer time between a photolithographic exposure process and a subsequent post exposure bake process.

7. The method of claim 1 wherein the time critical process comprises a time period associated with the end of a photoresist process and the beginning of a bake process.

8. The method of claim 1 further comprising adjusting the sending rate in response to the monitoring step.

9. A method of operating a cluster tool, the method comprising:
determining a first process step of a recipe, the recipe associated with a first substrate moving through the cluster tool, the first process step being associated with a first process time;
determining a second process step of the recipe, the second process step being associated with a second process time, wherein the second process step is a critical process step;
monitoring a duration of the second process step;
detecting a variation in the duration of the second process step; and
increasing a duration of the first process step in response to detecting a variation in the duration of the second process step, wherein an increase in duration of the first process step is substantially equal to the variation in the duration of the second process step.

10. The method of claim 9 wherein the first process step precedes the second process step in the recipe.

11. The method of claim 9 wherein the second process step is a transfer step between a scanner and a post exposure bake chamber.

12. The method of claim 9 wherein the second process step is a transfer step between a photoresist coating step and a photoresist bake step.

13. The method of claim 9 further comprising:
determining a third process step of the recipe;
decreasing the duration of the first process step; and
increasing a duration of the third process step, wherein the increase in the duration of the third process step is substantially equal to the decrease in duration of the first process step.

14. The method of claim 9 further comprising:
decreasing the duration of the first process step; and
delaying an introduction of a second substrate into the cluster tool by a delay time, the delay time being substantially equal to the decrease in duration of the first process step.

15. A computer readable medium storing a plurality of instructions for controlling a data processor to operate a semiconductor wafer cluster tool, the plurality of instructions comprising:
instructions that cause the data processor to determine a first process step of a recipe, the recipe associated with a first substrate moving through the cluster tool, the first process step being associated with a first process time;
instructions that cause the data processor to determine a second process step of the recipe, the second process step being associated with a second process time, wherein the second process step is a critical process step;
instructions that cause the data processor to monitor a duration of the second process step;
instructions that cause the data processor to detect a variation in the duration of the second process step; and
instructions that cause the data processor to increase a duration of the first process step in response to detecting a variation in the duration of the second process step, wherein an increase in duration of the first process step is substantially equal to the variation in the duration of the second process step.

16. The computer readable medium of claim 15 wherein the second process step is a transfer step between a scanner and a post exposure bake chamber.

17. The computer readable medium of claim 15 wherein the plurality of instructions further comprise:
instructions that cause the data processor to determine a third process step of the recipe;
instructions that cause the data processor to decrease the duration of the first process step; and
instructions that cause the data processor to increase a duration of the third process step, wherein the increase in the duration of the third process step is substantially equal to the decrease in duration of the first process step.

18. The computer readable medium of claim 15 wherein the plurality of instructions further comprise:
instructions that cause the data processor to decrease the duration of the first process step; and
instructions that cause the data processor to delay an introduction of a second substrate into the cluster tool by a delay time, the delay time being substantially equal to the decrease in duration of the first process step.

19. The computer readable medium of claim 15 wherein the first process step is a chill step.

20. The computer readable medium of claim 15 wherein the plurality of instructions further comprise instructions that cause the data processor to adjust a sending rate in response to monitoring the duration of the second process step.

21. A method of processing a plurality of substrates according to a recipe, the recipe including a plurality of process steps, a plurality of transfer steps, and one or more delay steps, the method comprising:
determining a fundamental period for the processing of the plurality of substrates;
transferring the plurality of substrates into a track lithography tool at the fundamental period;
monitoring a variation in the process time associated with at least one of the plurality of process steps or the plurality of transfer steps; and
increasing the duration of at least one of the one or more delay steps to compensate for the variation in the process time.

22. The method of claim 21 wherein the fundamental period is equal to a time period associated with a process step divided by a number of process modules dedicated to perform the process step.

23. The method of claim 21 wherein the variation in the process time comprises an increase in the process time.

24. The method of claim 23 wherein the duration of the at least one of the one or more delay steps is increased by a time equal to the variation in the process time.
